(19) United States
(12) Patent Application Publication
(10) Pub. No.: US 2022/0302733 A1
(43) Pub. Date: Sep. 22, 2022

(54) ADDRESSING PARASITICS IN A BATTERY CHARGING SYSTEM UTILIZING HARMONIC CHARGING

(71) Applicant: Iontra LLC, Denver, CO (US)

(72) Inventors: John Richard HOWLETT, III, Centennial, CO (US); Daniel A. KONOPKA, Denver, CO (US)

(21) Appl. No.: 17/698,890

(22) Filed: Mar. 18, 2022

Related U.S. Application Data
(60) Provisional application No. 63/163,022, filed on Mar. 18, 2021.

(51) Int. Cl. H02J 7/00

(52) U.S. Cl. CPC H02J 7/00712; H02J 7/0047

(57) ABSTRACT

Aspects of the present disclosure for charging or discharging a battery. During charging or discharging, a measurement of losses due to parasitic pathways may be obtained and an adjustment to a harmonic content of the charge signal may be made to reduce the parasitic losses. The charge signal may be composed of one or more harmonic components selected in response to a measured parasitic effect of the charge environment. The system may therefore generate a charge signal such that it includes the harmonic component, amplifies specific harmonic components, filters or suppresses harmonic components, shifts harmonic components and otherwise control the make-up of the charge signal focusing on the harmonic components of the signal and the effect on energy transfer to or from the battery. Alterations to the harmonic component of the charge signal may be made in response to a detected parasitic loss of a battery during charge.

### CROSS-REFERENCE TO RELATED APPLICATION

This application is related to and claims priority under 35 U.S.C. § 119 from U.S. Provisional Application No. 63/163,022 filed Mar. 18, 2021 entitled “ADDRESSING PARASITICS IN A BATTERY CHARGING SYSTEM UTILIZING HARMONIC CHARGING,” the entire contents of which are fully incorporated by reference herein for all purposes.

### TECHNICAL FIELD

Embodiments of the present disclosure generally relate to systems and methods for charging or discharging a battery, and more specifically for the controlled coordination of current to and from the battery to address and reduce parasitic effects of the charged or discharged battery.

### BACKGROUND

Many conventional charging systems, especially those used for mobile consumer products such as vacuums, power tools, portable speakers, etc., involve a DC charge current to a battery, which may be a cell or multiple cells connected in a “pack”. Upon depletion, the battery is either replaced or recharged. Recharging a battery may be inconvenient as the powered device must often be stationary during the time required for recharging the battery. As such, significant effort has been put into developing charging technology that reduces the time needed to recharge the battery.

Battery systems also tend to degrade over time, based on the charge and discharge cycling of the battery system and the depth of discharge and overcharging, among other possible factors. Thus, like the speed of charging, efforts are made to optimize charging to maximize battery life, not over discharge the battery, or overcharge the battery while using as much of the battery capacity as possible. Often these objectives are at odds, and charging systems are designed to optimize some attributes at the expense of others.

A relatively simple circuit for recharging a battery may include the application of a power signal generated by a power source to the electrodes of the battery to cause a reverse flow of electrons through the battery to replenish the stored concentration of charge carriers (such as lithium ions) at the anode. In one particular example, the power source may be a direct current (DC) voltage source to provide a DC charge current to the battery. Other types of power sources, such as a current controlled source, may also be used. The charge circuit may include other components to aid in charging or discharging of the battery, such as a current meter, volt-meter, controller, etc.

In exploring the effect of charge and discharge signals on a battery, various problems have been discovered. For example, given harmonic components or components of a typical recharge signal, which may also be referred to as AC components, a conventional charging environment may exhibit frequency dependent parasitics. The frequency dependent parasitics of a charge signal may take multiple forms. For example, parasitic inductance paths may be created at different frequencies of a charge signal, where the parasitic paths divert charge energy to ground (e.g., not to the batteries themselves), attenuate or distort the charge signal and the targeted harmonics presented therein. The conventional charging environment that may exhibit such parasitics includes, but is not limited to, the battery, various components of the battery, interconnections between cells of the battery, the shape of cells, connections to and between cells, monitoring hardware, electronics, chips, printed circuit boards, traces and mounting hardware, mechanical connectors and the like. However, as energy is being diverted to ground or other components other than the batteries themselves, efficiency and effectiveness of a charge signal may be dependent on the AC components of the charge signal.

It is with these observations in mind, among others, that aspects of the present disclosure were conceived and developed.

### SUMMARY

One aspect of the present disclosure relates to a method for charging a battery. The method may include during application of a charge signal to a battery, determining, with a processor, parasitic loss in the battery and adjusting a harmonic component of the charge signal to reduce the parasitic loss.

Another aspect of the present disclosure relates to a battery charging system. The system may include a processing unit including computer executable instructions. When the instructions are executed, the processing unit determines, from a charge current measurement, a parasitic loss when a battery is charged according to a charge signal and alters a harmonic component of the charge signal responsive to the determined parasitic loss.

Still another aspect of the present disclosure relates to a charging system that includes at least one component optimized to reduce parasitic loss present when a charge or discharge signal is present, where the charge or discharge signal includes a harmonic component designed to optimize battery charge or discharge.

### BRIEF DESCRIPTION OF THE DRAWINGS

The foregoing and other objects, features, and advantages of the present disclosure set forth herein should be apparent from the following description of particular embodiments of those inventive concepts, as illustrated in the accompanying drawings. The drawings depict only typical embodiments of the present disclosure and, therefore, are not to be considered limiting in scope.

FIG. 1 is a schematic diagram illustrating a first circuit for charging a battery in which parasitic losses are accounted in accordance with one embodiment.

FIG. 2 is a schematic diagram illustrating a second circuit for charging a battery in which parasitic losses are accounted in accordance with one embodiment.

FIG. 3 is a flowchart illustrating a method for adjusting a harmonic component of a charge or discharge signal of a battery to reduce parasitic effects in accordance with one embodiment.

FIG. 4 illustrates a system, according aspects of the present disclosure, that may be used to practice various aspects of the present disclosure

### DETAILED DESCRIPTION

Systems, circuits, and methods are disclosed herein for charging (recharging) or discharging a battery. The terms charging and recharging are used synonymously herein. Through the systems, circuits, and methods discussed, less energy may be required to charge a battery than through previous charging circuits and methods. Aspects of the present disclosure may provide several advantages, alone or in combination, relative to conventional charging. For example, the charging techniques described herein may allow for higher charging rates to be applied to a battery and may thus allow for faster charging. The techniques may allow optimum charge rates to be used, and which consider other issues such as cycle life and temperature. In one example, charge rates and parameters may be optimized to provide for a longer battery life and greater charging energy efficiency. In another example, in what might be considered “fast charging,” the disclosed systems and methods provide an improved balance of charge rate and battery life, while producing less heat. While previous charging circuits have attempted to address the efficiency of the charging circuits by focusing on the electronic devices of the charging circuits, the disclosed systems, circuits, and methods provide an efficient battery charge signal when applied to charge a battery.

As explained above, a conventional charging environment may exhibit frequency dependent parasitics that reduces the efficiency of the charge signal as energy is diverted away from the battery. For example, parasitic inductance paths may be created at different frequencies, where the parasitic paths divert charge energy to ground (e.g., not to the batteries themselves), attenuate or distort the charge signal and the targeted harmonics presented therein. Accordingly, an aspect of the present disclosure involves measuring losses due to parasitic pathways and adjusting the harmonic content of the charge signal to reduce the parasitic losses. Besides losses, in some environments such as electric vehicle, there may be fault circuitry that would be tripped if parasitic paths to chassis ground are too high, and thus reducing or eliminating the same is important in those environments. In another example, the harmonic content may be balanced to affect the energy transfer to the battery with parasitic energy losses. In another example, various hardware attributes, particularly of the battery, may be optimized to reduce parasitic losses at the range of harmonics designed and controlled for charge or discharge for the battery.

The various embodiments discussed herein may charge or discharge a battery by generating an energy transfer signal that corresponds to a harmonic (or harmonics) associated with an optimal transfer of energy based on measured loss due to parasitic pathways in the energy transfer to or from of the battery. In one example, the charge signal is composed of one or more harmonic components selected in response to a measured parasitic effect of the charge environment. The system may generate a charge signal such that it includes the harmonic component. The system may amplify specific harmonic components, may filter or suppress harmonic components, may shift harmonic components and otherwise control the make-up of the charge signal focusing on the harmonic components of the signal and the effect of those harmonics on energy transfer to or from the battery.

In one example, the various embodiments discussed herein charge a battery by generating a charge or discharge signal that is controllably shaped. The shapes may be tuned based on impedance effects of the battery to various harmonics. In some instances, the shape, which may include harmonic aspects, in charge or discharge, is tailored to be based on detected or measured parasitic effects of the battery and minimize damage to the battery or to achieve other effects. In some instances, during charging, the shape or content of the charge signal, which may also include harmonic aspects, is optimized for charge. The system may select harmonic attributes associated with relatively higher impedance as compared to charging where the system may control the charge signal to include harmonic attributes associated with relatively lower impedance. In other instances, or in addition, the system may select harmonic attributes to reduce a parasitic effect on the battery.

In one implementation, one or more control circuits may be included in a charge circuit to shape, alter, or generate a charge signal (e.g., charge current) corresponding to the determined harmonic profile of the charge signal based on the parasitic loss. In one instance, the control circuits may enhance portions of the charge signal associated with a harmonic or harmonics corresponding to a parasitic effect. Stated differently, the system may generate a charge signal enhancing and otherwise emphasizing harmonic components that more efficiently transfer energy to the battery in response to and to reduce a detected parasitic drain of the charging environment. In other instances, the control circuits may decrease portions of the charge signal associated with a harmonic or harmonics corresponding to a relatively large parasitic effect. Stated differently, the system may generate a charge signal suppressing and otherwise deemphasizing harmonic components that more oppose transfer of energy to the battery or otherwise are associated with various deleterious characteristics and effects. Of course, the system may be arranged to provide a charge signal that both enhances some harmonic components and suppresses other harmonic components. The circuits described herein may, in some instances, perform an iterative process of monitoring for one or more parasitic effects and adjusting the charge signal applied to the battery based on the harmonic profile. This iterative process may reduce parasitic losses and other effects while also improving the efficiency of the charge signal used to recharge the battery, thereby decreasing the time to recharge the battery, extending the life of the battery (e.g., the number of charge and discharge cycles it may experience), optimizing the amount of current charging the battery, manage temperature of the battery, and avoiding energy lost to various inefficiencies, among other advantages.

In some embodiments, the system may further use a model of one or more components of a charge/discharge signal shaping circuit. Conventional charge techniques like constant current or constant voltage do not involve charge signal shaping and hence control is relatively straightforward such that there is no need for the charge and discharge signal shaping techniques discussed herein. The model may be used to confirm and/or adjust the controls for generating the signal to or from the battery, and likely in combination to reduce a detected parasitic effect of the battery. In some instances, aspects of the shape and/or content of the charge signal may correspond to a harmonic (or harmonics) associated with an optimal transfer of energy to the battery, although one overall purpose of the system is to be able to efficiently generate any arbitrarily shaped charging signal and apply the same to the battery, among other goals. Other instances may involve shaping and/or defining a signal intended to reduce or minimize parasitic effects. The shape or signal content, which may be any arbitrary shape defined by the controls and, in some instances includes defined harmonic content, is nonetheless controlled.

Aspects of the system, whether using a model or not, may further include feedback of battery parameters both during the charging or discharging phase, such as a feedback of current measurements at the electrodes of the battery. Feedback, alone or in conjunction with a model, may allow the system to adjust for component drift, adjust for effects of temperature or other effects on circuit components, adjust for changes in the battery, and periodically provide additional data to the system and/or the model to alter its output, among other things.

The various implementation discussed herein involving charging and discharging, in conjunction with reducing or removing parasitic effects, are applicable to electrochemical devices such as batteries. The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different type of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries, to name a few. The various implementations discussed herein may also apply to different structural battery arrangements such as button or “coin” type batteries, cylindrical cells, pouch cells, and prismatic cells.

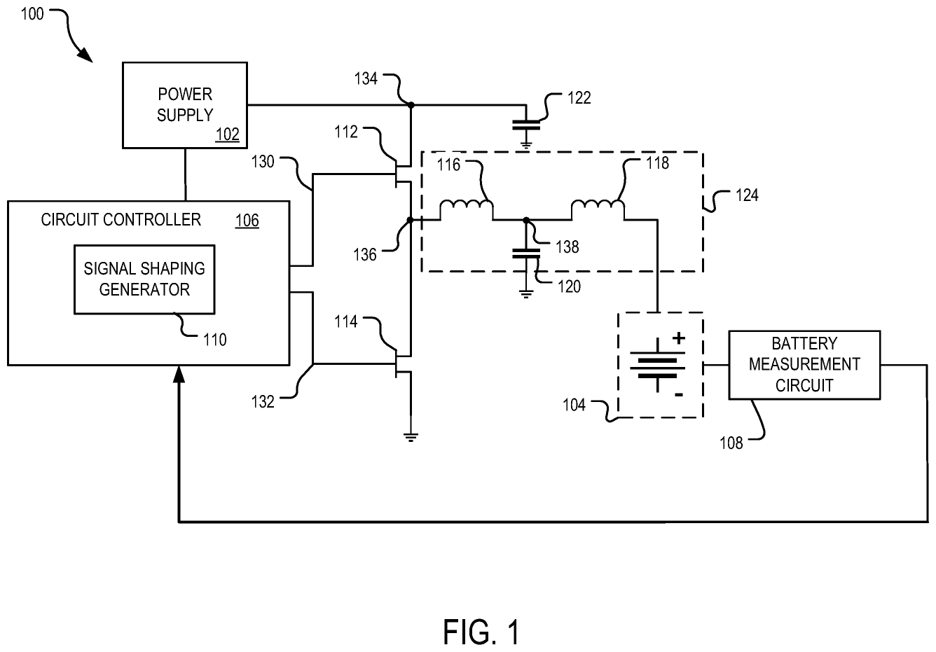

FIG. 1 is a schematic diagram illustrating an example charge signal generator arrangement 100 for charging and/or discharging a battery 104. The circuit 100 includes a processing unit or more generally a control unit 106 that may include a controller, such as a microcontroller, FPGA (field-programmable gate array), ASIC (application-specific integrated circuit), microprocessor, combinations thereof, or other processing arrangement, which may be in communication with a signal generator that produces controls for generating a charge signal from a charge signal shaping circuit 110. In some instances, the controller may be in communication with a model, which may be part of the generator, to produce the control instructions to the charge signal shaping circuit 110. The system may also receive feedback including battery measurements from a battery measurement unit 108, such as current and/or voltage measurements at battery terminals of the battery 104 in the presence of a signal (charge and/or discharge), and those battery measurements may be used to obtain impedance measurements, parasitic measurements, and/or affect charge control. For example, the battery measurement circuit 108 may include one or more current sensors to measure current into and/or out of the battery 104. In another example, the battery measurement circuit 108 may include a voltmeter to measure the voltage across the battery electrodes. Some characteristics of the battery 104 may also be derived from the measurements, such as the current into or out of the battery may be derived from a voltage measurement of the battery, and vice versa. In general, the controller 106 may also include or be operably coupled with a power source 102, which may be a voltage source or a current source. In one embodiment, the power source 102 is a direct current (DC) current or voltage source, although alternating current (AC) sources are also contemplated. In various alternatives, the power source 102 may include a DC source providing a unidirectional current, an AC source providing a bidirectional current, or a power source providing a ripple current (such as an AC signal with a DC bias to cause the current to be unidirectional. In general, the power source 1002 supplies the charge energy, e.g., current, that may be shaped or otherwise defined by the circuit controller 106 to produce a controllably shaped charge signal to charge and/or discharge the battery 104. In one example, the controller 106 may provide one or more inputs to the signal generator 110, which controls switches to generate pulses which may also filtered through other components of the circuit to produce the shaped signal at the battery.

In some instances, the signal shaping circuit 110 may alter energy from the power source 102 to generate a signal that is shaped based on conditions at the battery 104, such as a signal that at least partially corresponds to a harmonic or harmonics based on the parasitic effects when a signal comprising the harmonic or attributes of the harmonic is applied to the battery 104. In the example of FIG. 1 and otherwise, the circuit 100 may include the battery measurement unit 108 connected to the battery 104 to measure battery voltage and/or charge current, as well as other battery attributes like temperature and measure, calculate or otherwise obtain the parasitic effect at the battery 104 based on the same. In one example, battery characteristics may be measured based on the signal to or from the battery. In another example, battery cell characteristics may be measured as part of a routine that applies a signal with varying frequency attributes to generate a range of battery characteristic values associated with the different frequency attributes to characterize the battery, which may be done prior to charging or discharging, during charging, periodically during the same, and may be used in combination with look-up techniques, and other techniques. The battery characteristics may vary based on many physical of chemical features of the battery, including a state of charge and/or a temperature of the battery. As such, the battery measurement circuit 108 may be controlled by the controller 106 to determine various battery characteristic values of the battery 104 during charging or discharging of the battery and provide the measured of battery characteristic values to the controller 106 or other parts of the circuit 100.

During charge, the controller 106 may generate an intended charge signal for efficient charging of the battery 104. For example, a determined impedance of the battery 104 or signal definitions characterized from understanding impedance effects of signals on a battery may be used by the controller 106 to generate or select a charge signal with attributes that correspond to a harmonic associated with an optimal impedance, which may be a range of impedances, for energy transfer, which optimal impedance may be associated with a minimum impedance value of the battery 104. As such, the controller 106 may execute a charge signal algorithm that outputs a charge signal shape based on measured, characterized and/or estimated charging conditions of the battery 104. Generally speaking, the signal generator 110 controls the switches 112, 114 to generate a sequence of pulses at node 136, which are converted by circuit 124 to the charge signal shape. Similarly, parasitic effects of the battery 104 may be characterized, based on one or more current measurements into or out of the battery, to understand such effects on the battery during charge or discharge and a signal controlled based on the same. Here, the node 136 may similarly be controlled but such that current with defined impedance attributes is both sourced to and sunk from the battery. In some situations, the system may be used to controllably discharge the battery such as to warm the battery, which may occur in close synchronization with charging current, if it is below specified thresholds. The circuit controller 106 may generate one or more control signals based on a charge signal algorithm and provide those control signals to the signal shaping unit. The control signals may, among other functions, shape or otherwise define the signal to and from the battery 104 to approximate the shaped charge signal determined, selected or otherwise obtained by the controller 106. In some instances, the shaped charge signal may be any arbitrarily shaped signal, such that the signal charging or discharging, is not a constant DC signal and does not conform to a conventional repeating charge signal, such as a repeating square wave or triangle wave charge signal.

As shown, the circuit 100 may include one or more components to shape a signal to minimize frequency dependent parasitics that reduces the efficiency of the charge signal through diversion of energy away from the battery. For example, the circuit 100 may include a first switching element, e.g., transistor 112, and a second switching element, e.g., transistor 114, with the first switching element connected to the power rail 134 and thereby connected to the power supply 102 during charge and coupled to a capacitor 122. The capacitor 122 may have various functions including storage of power from the power source 102 when not directed to the battery 104 and providing some of the energy for a charge waveform. The first transistor 112 may receive an input signal, such as pulse-width modulation (PWM) control signal 130, to operate the first transistor 112 as a switching device or component. In general, the first transistor 112 may be any type transistor, e.g., a FET or more particularly a MOSFET, a GaN FET, Silicon Carbide based FETs, or any type of controllable switching element. For example, the first transistor 112 may be a FET with a drain node connected to a first inductor 116, a source connected to the rail 134, and a gate receiving the control signal 130 from the signal generator 110. In various embodiments, the circuit 124 also includes the inductor 116, but may also have various other possible inductive elements. For example, inductor 116 and or inductor 118 may be substituted with a transformer, where each or both sides (e.g., primary and secondary sides) of the transformer may be considered inductive elements. The control signal 130 may be provided by the circuit controller 106 to control the operation of the first transistor 112 as a switch that, when closed, connects the first inductor 116 to the power supply 102 such that a current from the power supply flows through the first inductor 116.

The second transistor 114 may receive a second input signal 132 and may also be connected to the drain of the first transistor 112 at node 136. In some instances, the second input signal 132 may be a PWM signal opposite of the first control signal 130 to the first transistor 112. In alternative arrangement, transistor 114 may be substituted with a diode. Nonetheless, when the first transistor 112 is closed to connect the first inductor 116 to the power supply 102, the second transistor 114 is open. When the first transistor 112 is open, conversely, the second transistor 114 is closed, connecting node 126 and the first inductor 116 to ground. Although the first control signal 130 and the second control signal 132 are described herein as opposing signals to control the transistors into opposing states, other techniques for controlling the switching elements 112, 114 may also be implemented with the circuit 100. The inductor value, the capacitor value, the time and frequency of actuating the transistors, and other factors can be tailored to generate a waveform and particularly a waveform with controlled harmonics to the battery for charging the same.

In addition to the first inductor 116, other components may be included in the circuit 100. In circuit portion 124, a second capacitor 120 may be connected between the first inductor 116 (at node 138) and ground. A second inductor 118 may be connected between node 138 and an anode of the battery 104. The circuit portion 124 may operate, in general and among other functions, to prevent rapid changes to the charge signal applied to the battery 104 and to convert the pulses at node 136 to a charge signal. For example, upon closing of the first transistor 112 based on control signal 130, first inductor 116 and second inductor 118 may prevent a rapid increase in current transmitted to the battery 104. Such rapid increase in current may damage the battery 104 or otherwise be detrimental to the life of the battery. Moreover, the inductor 116 or inductor 118, alone or in combination with capacitor 120, may shape the waveform applied to the battery, and control of the signal applied to the inductors may provide for controlled shaping of the waveform. In another example, capacitor 120 may store energy from the power supply 102 while first transistor 112 is closed. Upon opening of the first transistor 112, which may be accompanied by closing transistor 114, the capacitor 120 may provide a small amount of current to the battery 104 through second inductor 118 to resist an immediate drop of current to the battery, and may similarly be used to controllably shape the waveform applied to the battery, particularly avoiding a sharp negative transitions. The circuit portion 124 may also remove other unwanted signals, such as noise which may include relatively high frequency noise. Other advantages for charging of the battery 104 are also realized through circuit 124 but are not discussed herein for brevity.

It should be appreciated that more or fewer components may be included in charge circuit 100. For example, one or more of the components of the circuit 124 may be removed or altered as desired to shape the charge signal to the battery 104. Many other types of components and/or configurations of components may also be included or associated with the charge circuit 100. Rather, the circuit 100 is but one example of a battery charging circuit and the techniques described herein for utilizing the circuit to generate otherwise control signals 130, 132 for shaping a charge signal may apply to any number of battery charging circuits. Additionally, various additional combinations of inductors or capacitors may be provided in series or parallel to those illustrated.

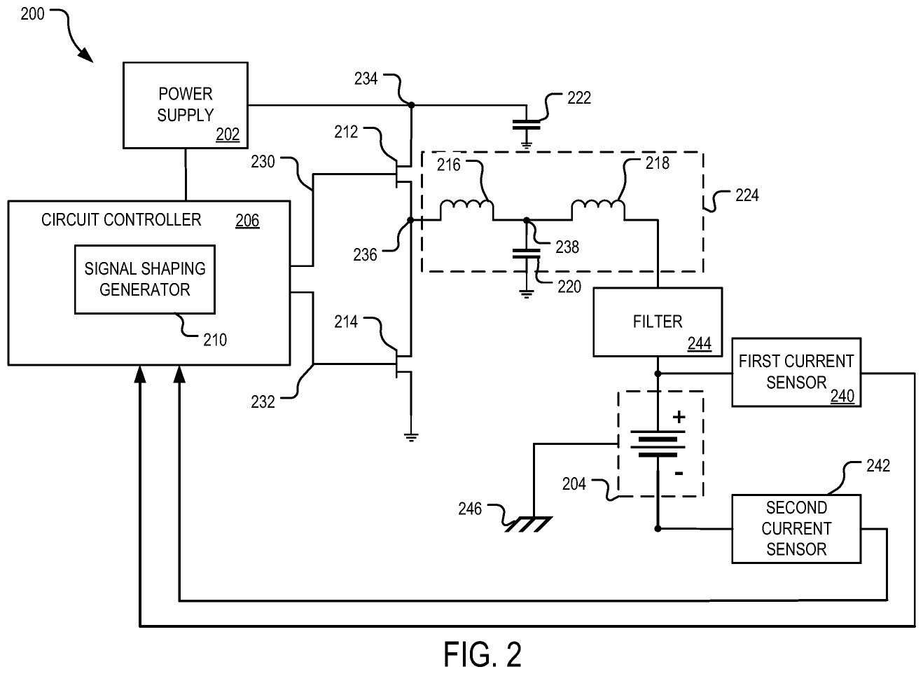

FIG. 2 is a schematic diagram illustrating an alternate circuit 200 for charging a battery in which parasitic losses are accounted for in accordance with one embodiment. The circuit 200 of FIG. 2 is an alternative version of the charge circuit 100 described above with reference to FIG. 1 and may include similar components, such as a power supply 202, a first transistor 212 or other type of electronic switch, second transistor 214, battery 204, and circuit controller 206. Other components are similar to, and operate in a similar way, as described above with reference to the circuit 100 of FIG. 1.

In this example, the circuit controller 206 controls one or more components of the circuit 200 to supply a charge signal to a battery 204, with the charge signal having at least one harmonic component. The frequency of the harmonic component may cause a parasitic pathway within the circuit, such as to chassis ground 246, to ground, or between other components of the system. While one parasitic path is illustrated, charging systems may have more than one such path, and the paths may be responsive to different frequencies. Regardless, in this example, the parasitic pathway diverts some portion of the charge signal to ground 246 rather than applying that portion of the charge signal to charging the battery 204. As noted above, the battery may be a single cell or a combination of cells, connected in various possible series and parallel combinations to provide the capacity, output current, and the like for the environment. For example, an electric vehicle may involve hundreds of cells, whereas a power tool may involve one or a small number of cells.

Regardless of the battery configuration, the charging system 200 may include a current sense at both the positive and negative terminals of the battery 204 measuring current into the battery and out of the battery, respectively. For example, a first current sensor 240 may be connected with the positive terminal of the battery 204 and a second current sensor 242 may connected to the negative terminal of the battery. In this particular configuration, the system 200 may measure parasitic loss at or within the battery 204 such that the current sensors 240, 242 are positioned proximate the terminals of the battery. In addition, or alternatively, the current sensors 240, 242 may be positioned or connected at other locations within the circuit 200 to measure parasitics at other or additional components to the battery 204. For example, if the sense lines from the first current sensor 240 and the second current sensor 242 are positioned at a charge connection, it may be possible to assess parasitic losses in the battery 204, as well as in the charge lines between the plug and the battery. The sense lines, similarly, may be positioned in a charger, with losses detected between the charger and the battery 204, including the battery. Regardless, the current sensors 240, 242 are each connected to the circuit controller 206 or other processing unit capable of processing the sensed measurements to receive the measured current obtained by the current sensors. For example, first current sensor 240 may provide an output value to the circuit controller 206 that corresponds to a sensed current at the positive terminal of the battery 204. Similarly, the second current sensor 242 may provide an output value to the circuit controller 206 that corresponds to a sensed current at the negative terminal of the battery 204. In some instances, the current into and/or out of the battery 204 may be derived from other measurements, such as deriving the current of the battery based on a voltage measurement across the battery.

The circuit controller 206 may process the sensed signals from the current sensors 240, 242, compute information from the sensed signals, and/or control the charge signal provided to the battery 204 based on the sensed signals. In some implementations, the circuit controller 206 may be integral to a charger or may otherwise be in communication with the charger. Regardless and to assess parasitic loss, the circuit controller 206 may determine a difference between the input current measured by the first current sensor 240 and the output current measured by the second current sensor 242. Absent any parasitic loss, there would be no or little difference between the input current and the output current. As such, any determined difference between the current measurements may be attributable in whole or in part to parasitic losses within the circuit 200. As explained in greater detail below, the circuit controller 206 may control one or more components of the circuit 200, such as the signal shaping generator 210 or the switching devices 212, 214 to alter a charge signal in response to the current measurements received from the first current sensor 240 and/or the second current sensor 242.

Some aspects of the present disclosure involve various possible hardware configurations to reduce parasitic paths and losses. In one example, the circuit 200 may also include a filter 244 circuit or component(s) connected to an electrode of the battery 204. The filter 244 may be generalized to all harmonics and/or may be tailored to a known frequency spectrum of harmonics in charge (or discharge) signals that will be applied to any given pack or type of pack. The filter 244 may, in some instances, include one or more tunable components that are controllable, such as from signals generated by the circuit controller 206, to filter harmonics of the charge signal to the battery 204 based on the current measurements provided to the circuit controller 206. In another example, hardware changes involving the pack and cell shape, cell isolation such as through high dielectric shielding, cell spacing, interconnection type and pathways between cells, interconnection routes, material types and shapes for various components, and otherwise, may also be included in the circuit 200 in response to a detected parasitic loss at the battery 204 or other component. In one specific example, the current sensors 240, 242 themselves may include inductive elements—typical of Hall Effect type current sensors, for example. Thus, in one example, the inductive portion of the sensor may be tailored to minimize the parasitic loss at the frequencies of the harmonics that will typically be applied to and/or from the battery 204. It should be noted, that different systems will often include different batteries, and the differences may be significant due to size, number of cells, types of cells, capacity, charge and discharge magnitudes and ranges, etc. Accordingly, optimal harmonics for any given battery system may also be different. As such, the parasitic loss tuning of a Hall Effect sensor or other components may be tailored to the system environment in which the component, e.g., Hall Sensor, is operating.

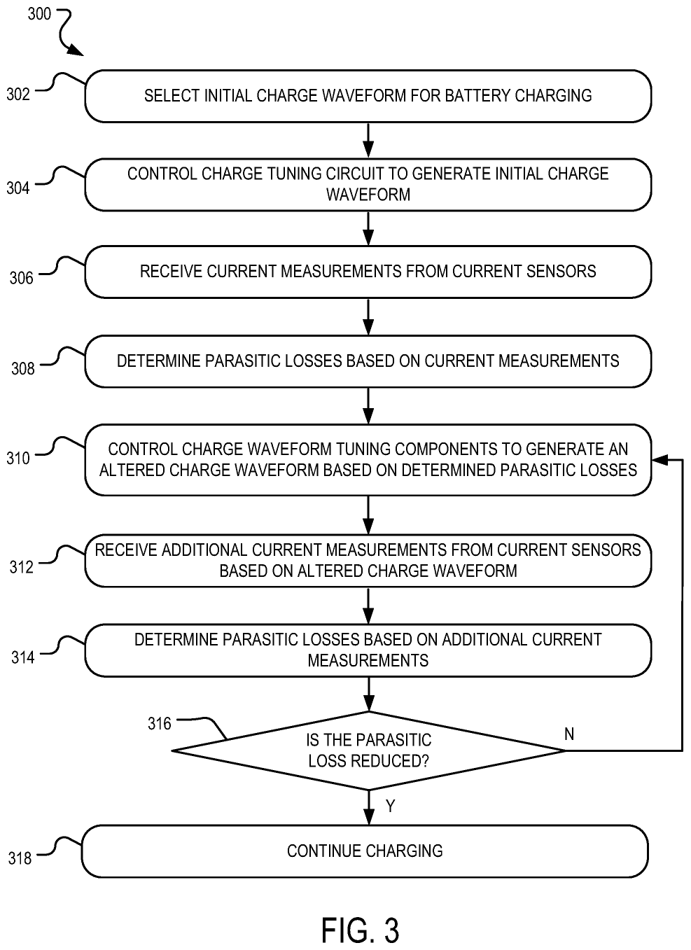

FIG. 3 is a flowchart illustrating a method for adjusting a harmonic component of a charge or discharge signal of a battery to reduce parasitic effects in accordance with one embodiment. In this example, reference may be made to the circuit of FIG. 2, but the method 300 is not limited to practice with the circuit. Rather, FIG. 2 depicts but one possible example of a system configuration consistent with the present disclosure. It should be recognized that harmonic components of a charge signal may change during the course of a charge sequence for reasons besides reducing parasitic loss, such as due to impedance characteristics of the battery 204 changing due to state of charge, temperature, and the like. Thus, the method 300 depicted in FIG. 3 may be executed periodically and/or in response to changes in the charge signal, changes to the operating conditions of the system 200, changes to the battery 204, and otherwise. Further, the operations of the method 300 may be performed, at least partially, by the circuit controller 206.

Beginning in operation 302, the circuit controller 206 may select an initial charge waveform for a charge signal to be used to charge the battery 204. In the initial operation and in some possible implementations, the charge signal may be considered a characterization signal, which may impart some charge but is intended to generate a profile. In one example, the initial charge waveform may be selected by the circuit controller 206 to minimize or reduce the real impedance at the battery 204 during the initial charging of the battery. Other characteristics, such as state of charge, temperature, and the like may or may not be known but may nonetheless be used to generate the initial charge waveform. In one particular example, the circuit controller 206 may select the initial charge waveform based on the state of charge, temperature, historical data of the battery 204, historical data of other batteries of the same type, historical data of the circuit controller, or other battery recharge data. The circuit controller 206 may select a charge signal with some known harmonic or frequency attribute based on the type of battery, the state of charge, the number of cycles, and/or the temperature. In some instances, the charge signal may be selected from some known set of charge signals and some predetermined knowledge of the effect of those charge signals on the battery. The known set of charge signal may be based on characterization of the same type of battery. For example, it may be known that some particular harmonic component or combination of components correspond to a relatively low impedance for a typical battery of the same temperature, state of charge, charge history, and/or otherwise. In another example, the circuit controller 206 may analyze previous charging sessions of the battery 204 or other batteries. Based on the analysis, the circuit controller 206 may estimate a harmonic for the battery 204 at which the impedance, real or complex, of the battery is at or near a minimum and generate an initial charge waveform which includes a large harmonic component. Similarly, the initial charge waveform may suppress harmonics at other frequencies.

In another example, the circuit controller 206 may access a stored model of the battery 204 or charge circuit 200. The circuit model may model the components the circuit 200, such as power supply 202, first transistor 212, second transistor 214, and inductor 216 to estimate a current waveform at the battery 204. Additional components, such as components of circuit 224, may also be included in the circuit model. The components included in the model may have varying attributes to determine the effect of the component on an applied charge signal. For example, the model may include an inductance and an equivalent series resistance value associated with the inductor 216. The attributes of the modeled components may be adjusted over time based on performance data or feedback data from the circuit components. For example, the charge signal of the circuit 200 may be sampled and fed back to the circuit controller 206 at various points and a comparison of the received charge signal to an expected charge signal may be made by the controller. Based on a difference, the circuit controller 206 may alter or adjust one or more attributes of the components of the model to improve the accuracy of the model. The adjustments to the model components may be repeated over a period of time such that the adjustments may account for parasitic effects to the components.

Regardless of how the initial charge waveform was selected, the circuit controller 206 may provide one or more control signals to the charge signal shaping generator 210 to generate the initial charge waveform at operation 304, as described above. However, the parasitic losses within the circuit 200, such as at the battery 204, due to harmonics within the initial charge signal may reduce the charging efficiency of the initial signal. As such, altering the charge waveform in response to a determined parasitic loss of the battery 204 may provide benefits to charging the battery. Thus, in operation 306, the circuit controller 206 may receive current measurements from one or more current sensors 240, 242 of the circuit 200 and, in operation 308, determine parasitic losses based on the received current measurements. The determined parasitic losses may be determined through a calculated difference between the received current measurements as a difference in the current into the battery 204 to the current out of the battery may be associated with a parasitic loss at the battery. In general, however, the circuit controller 206 may utilize any technique or algorithm to determine or estimate parasitic losses at the battery 204 or the circuit 200.

At operation 310, the circuit controller 206 may control one or more components of the circuit 200 to generate an altered charge waveform based on the determined parasitic losses. For example, the circuit controller 206 may determine a difference in the received current measurements and, based on this determined difference, the signal shaping generator 210 may control, via control signals 230, 232, the first transistor 212 and the second transistor 214 to adjust the shape of the charge signal to the battery 204. In other words, the signal shaping generator 210 may sculpt the charge signal transmitted to the battery 204 to remove or alter a harmonic of the charge signal. In some instances, specific harmonics may be suppressed, ranges above or below a threshold frequency or frequencies may be suppressed, harmonics may be added, harmonics removed, or both added and removed, etc. may be adjusted. The choice of harmonic alternations may involve assessing harmonics based on the impedance characteristics of the battery and choosing harmonics to alter based on an additional assessment of how the harmonic change may impact the efficiency and efficacy of the charge signal to the battery. For example, as mentioned above, the initial charge waveform may be selected by the circuit controller 206 to minimize or reduce the real impedance at the battery 204 or on any other characteristic of the battery. The harmonics chosen, therefore, to be altered in response to the determined difference in current measurements may be made such that the impact on the impedance at the battery is minimized.

In any event, after the charge signal is altered, the circuit controller 206 may receive additional current measurements from the current sensors 240, 242 as the altered charge signal is provided to the battery 204 in operation 312. In operation 314, the circuit controller 206 may reassess the parasitic loss based on the additional current measurements to determine if further alterations of the charge signal are warranted. For example, as the altered charge waveform may suppressed or changed harmonics, the parasitic losses at the battery 204 may also be altered as the charge signal is provided to the battery such that the measured currents from the current sensors 240, 242 may be different from above. In some instances, the altered charge waveform may not change the measured currents.

At operation 316, the circuit controller 206 may determine if the parasitic loss decreases based on the additional current measurements received from the current sensors 240, 242. If the parasitic loss is reduced, the charge signal may continue with the selected set of harmonics at operation 318 to improve the efficiency of the charge signal provided to the battery 204. However, if the parasitic loss is not reduced, the circuit controller 206 may return to operation 310 to again adjust the charge signal to further alter harmonics and further reduce losses through the operations described above. This iterative process may continue with different alterations to the charge signal until the determined parasitic losses are reduced.

In addition, if the circuit controller 206 determines that the parasitic losses increase due to the altered charge signal in operation 316, the change made to the signal in operation 310 may be reversed and other changes attempted, with the method repeating as illustrated. For example, a first change to a harmonic of the charge signal may be undone and a second change to another harmonic of the signal may be executed, and the process may continue. In still other instances, if there is no change to the parasitic loss as determined in operation 314, other changes, such as changes to the filter 244 or one or more physical alterations to the battery 204 may be attempted. Various operations may be done in conjunction; for example, before altering a harmonic to reduce loss, the circuit controller 206 may assess the impact on charge efficiency. For example, the circuit controller 206 may not alter a harmonic of the charge signal if the harmonic corresponds to an impedance at the battery 204 or other characteristic. It should be further recognized that the parasitic loss method 300 described herein may also be practiced when the discharge signal is harmonically controlled in addition to or alternative to harmonically controlling the charge signal. In general, the harmonics of the charge signal may be altered in any manner to address a determined parasitic loss of the battery 204 or charge circuit 200.

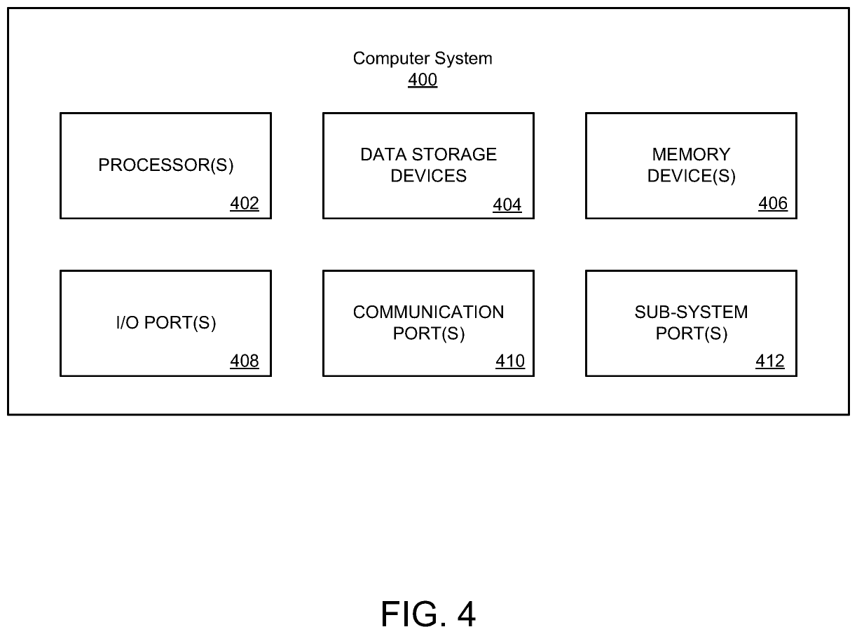

Referring to FIG. 4, a detailed description of an example computing system 400 having one or more computing units that may implement various systems and methods discussed herein is provided. The computing system 400 may be part of a controller, may be in operable communication with various implementation discussed herein, may run various operations related to the method discussed herein, may run offline to process various data for characterizing a battery, and may be part of overall systems discussed herein. The computing system 400 may process various signals discussed herein and/or may provide various signals discussed herein. For example, battery measurement information, such as the current signals from first current sensor 240 and/or second current sensor 242, may be provided to such a computing system 400. The computing system 400 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 400 may be a computing system that is capable of executing a computer program product to execute a computer process. Data and program files may be input to the computer system 400, which reads the files and executes the programs therein. Some of the elements of the computer system 400 are shown in FIG. 4, including one or more hardware processors 402, one or more data storage devices 404, one or more memory devices 406, and/or one or more ports 408-412. Additionally, other elements that will be recognized by those skilled in the art may be included in the computing system 400 but are not explicitly depicted in FIG. 4 or discussed further herein. Various elements of the computer system 400 may communicate with one another by way of one or more communication buses, point-to-point communication paths, or other communication means not explicitly depicted in FIG. 4. Similarly, in various implementations, various elements disclosed in the system may or not be included in any given implementation.

The processor 402 may include, for example, a central processing unit (CPU), a microprocessor, a microcontroller, a digital signal processor (DSP), and/or one or more internal levels of cache. There may be one or more processors 402, such that the processor 402 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 404, stored on the memory device(s) 406, and/or communicated via one or more of the ports 408-412, thereby transforming the computer system 400 in FIG. 4 to a special purpose machine for implementing the operations described herein.

The one or more data storage devices 404 may include any non-volatile data storage device capable of storing data generated or employed within the computing system 400, such as computer executable instructions for performing a computer process, which may include instructions of both application programs and an operating system (OS) that manages the various components of the computing system 400. The data storage devices 404 may include, without limitation, magnetic disk drives, optical disk drives, solid state drives (SSDs), flash drives, and the like. The data storage devices 404 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 406 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 404 and/or the memory devices 406, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 400 includes one or more ports, such as an input/output (I/O) port 408, a communication port 410, and a sub-systems port 412, for communicating with other computing, network, or vehicle devices. It will be appreciated that the ports 408-412 may be combined or separate and that more or fewer ports may be included in the computer system 400. The I/O port 408 may be connected to an I/O device, or other device, by which information is input to or output from the computing system 400. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 400 via the I/O port 408. In some examples, such inputs may be distinct from the various system and method discussed with regard to the preceding figures. Similarly, the output devices may convert electrical signals received from computing system 400 via the I/O port 408 into signals that may be sensed or used by the various methods and system discussed herein. The input device may be an alphanumeric input device, including alphanumeric and other keys for communicating information and/or command selections to the processor 402 via the I/O port 408.

The environment transducer devices convert one form of energy or signal into another for input into or output from the computing system 400 via the I/O port 408. For example, an electrical signal generated within the computing system 400 may be converted to another type of signal, and/or vice-versa. In one implementation, the environment transducer devices sense characteristics or aspects of an environment local to or remote from the computing device 400, such as battery voltage, open circuit battery voltage, charge current, battery temperature, light, sound, temperature, pressure, magnetic field, electric field, chemical properties, and/or the like.

In one implementation, a communication port 410 may be connected to a network by way of which the computer system 400 may receive network data useful in executing the methods and systems set out herein as well as transmitting information and network configuration changes determined thereby. For example, charging protocols may be updated, battery measurement or calculation data shared with external system, and the like. The communication port 410 connects the computer system 400 to one or more communication interface devices configured to transmit and/or receive information between the computing system 400 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 410 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 400 may include a sub-systems port 412 for communicating with one or more systems related to a device being charged according to the methods and system described herein to control an operation of the same and/or exchange information between the computer system 400 and one or more sub-systems of the device. Examples of such sub-systems of a vehicle, include, without limitation, motor controllers and systems, battery control systems, and others.

The system set forth in FIG. 4 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed:

1. A method of charging a battery, the method comprising:
during application of a charge signal to a battery, determining, with a processor, parasitic loss in the battery; and
adjusting a harmonic component of the charge signal to reduce the parasitic loss.

2. The method of claim 1, wherein determining parasitic loss in the battery comprises:
controlling a charge circuit to generate an initial charge signal; and
determining a difference of a plurality of current measurements, each of the plurality of current measurements received from respective a current sensor in electrical communication with the battery.

3. The method of claim 2 wherein the parasitic loss in the battery is associated with the determined difference of the plurality of current measurements.

4. The method of claim 2 wherein a first current sensor is in electrical communication with a first electrode of the battery and a second current sensor is in electrical communication with a second electrode of the battery.

5. The method of claim 1 wherein the determined parasitic loss in the battery is based on a voltage measurement of the battery.

6. The method of claim 1 further comprising:
determining a change in the parasitic loss after adjusting the harmonic component of the charge signal; and
further adjusting the charge signal to reduce the parasitic loss.

7. The method of claim 6 wherein further adjusting the charge signal comprises:
adjusting the harmonic component of the charge signal to a pre-adjustment value; and
adjusting a different harmonic component of the charge signal to reduce the parasitic loss.

8. The method of claim 1 wherein adjusting the harmonic component of the charge signal comprises:
iteratively adjusting a plurality of harmonic components of the charge signal; and
determining a change in the parasitic loss after each iterative adjustment of the plurality of harmonic components of the charge signal; and
if the parasitic loss is reduced, ending the iterative adjustment of the plurality of harmonic components of the charge signal.

9. The method of claim 1 wherein adjusting the harmonic component of the charge signal comprises adjusting a plurality of harmonic component of the charge signal to reduce the parasitic loss.

10. The method of claim 1 further comprising:
controlling the charge signal to include a harmonic component associated with a minimum impedance value of the battery.

11. The method of claim 1 further comprising:
adjusting a filter circuit to filter the harmonic component of the charge signal to reduce the parasitic loss.

12. A battery charging system comprising:
a processing unit including computer executable instructions to:
from a charge current measurement, determine a parasitic loss when a battery is charged according to a charge signal; and
alter a harmonic component of the charge signal responsive to the determined parasitic loss.

13. The battery charging system of claim 11 further comprising a current sensor positioned to measure an input charge current to the battery and an output current from the battery.

14. The battery charging system of claim 11 further comprising:
a first switch in communication with the processing unit, the processing unit controlling the first switch to alter the harmonic component of the charge signal;
a second switch in communication with the first switch at a common node, the common node operably coupled with a first inductive element.

15. The battery charging system of claim 14 further comprising a second inductor coupled with the first inductive element, the battery operably coupled with the second inductor to receive the altered charge signal, and a capacitor coupled between the first inductor and the second inductor.

16. The battery charging system of claim 12 wherein the processing unit comprises a microcontroller.

17. The battery charging system of claim 12 wherein the harmonic component of the charge signal is altered to reduce the parasitic loss.

18. The battery charging system of claim 12 further comprising a filter component, wherein the filter component is altered based on the determined parasitic loss when the battery is charged.

19. A charging system including at least one component optimized to reduce parasitic loss present when a charge or discharge signal is present, where the charge or discharge signal includes a harmonic component designed to optimize battery charge or discharge.

20. The charging system of claim 19 to determine, with a processor, the parasitic loss in a battery when the charge or discharge signal is present, the parasitic loss based on at least two current measurements associated with the battery.

21. The charging system of claim 19 to determine a change in the parasitic loss present after optimizing the at least one component and further optimize the at least one component to reduce the parasitic loss present.
